(19) United States
(12) Patent Application Publication
(10) Pub. No.: US 2025/0280689 A1
(43) Pub. Date: Sep. 4, 2025

(54) Display Device

(71) Applicant: LG Display Co., Ltd., Seoul (KR)

(72) Inventors: Yun Ho Kook, Paju-si (KR); Seung Hee Nam, Paju-si (KR)

(21) Appl. No.: 18/658,448

(22) Filed: May 8, 2024

(30) Foreign Application Priority Data
Feb. 29, 2024 (KR) 10-2024-0030057

(51) Int. Cl. H10K 59/35; H10K 59/122; H10K 59/131; H10K 59/80

(52) U.S. Cl. CPC H10K 59/353; H10K 59/122; H10K 59/131; H10K 59/351; H10K 59/878

(57) ABSTRACT

Embodiments of the disclosure relate to a display device with an enhanced VACS, and may provide a display device comprising a subpixel including a first area overlapping an organic light emitting diode and a second area not overlapping the organic light emitting diode and disposed to surround an outer periphery of the first area, a main emission area disposed in the first area, and a reflected light area disposed to surround an outer periphery of the main emission area in the second area and having one side portion protruding outward to form a protruding area.

### CROSS-REFERENCE TO RELATED APPLICATION

This application claims priority from Republic of Korea Patent Application No. 10-2024-0030057, filed on Feb. 29, 2024, which is hereby incorporated by reference in its entirety.

### BACKGROUND

### Field

Embodiments of the disclosure relate to a display device with enhanced viewing angle color shift (VACS) characteristics.

### Description of Related Art

In recent years, the display sector for visually representing electrical information signals has developed rapidly in the information era, and various display devices with excellent performance, such as more compact, lightweight, and low power consumption displays, have been developed accordingly.

Specific examples of display devices include liquid crystal displays (LCDs), field emission displays (FEDs), and organic light emitting displays (OLEDs).

Meanwhile, the display device may display an image through an arrangement of red, green, and blue subpixels in a matrix form. Since these subpixels each output a different wavelength depending on the color, there is a difference in luminance reduction depending on the viewing angle. Therefore, the viewing angle color shift (VACS) characteristics may deteriorate from the front to the side.

### SUMMARY

Embodiments of the disclosure may provide a display device with enhanced viewing angle color shift (VACS) characteristics by controlling the distance between the opening of the bank layer and the reflective electrode depending on the wavelength for each subpixel.

Embodiments of the disclosure may provide a display device capable of enhancing the VACS without reducing the aperture ratio.

Embodiments of the disclosure may provide a display device with enhanced luminance as light traveling from the light emitting layer to the side surface is re-reflected by the reflective electrode to the outside.

Embodiments of the disclosure may provide a display device capable of reducing power consumption as the light extraction efficiency is enhanced by the reflective electrode.

Embodiments of the disclosure may provide a display device comprising a subpixel including a first area overlapping an organic light emitting diode and a second area not overlapping the organic light emitting diode and disposed to surround an outer periphery of the first area, a main emission area disposed in the first area, and a reflected light area disposed to surround an outer periphery of the main emission area in the second area, and having one side portion protruding outward to form a protruding area.

According to embodiments of the disclosure, there may be provided a display device with enhanced viewing angle color shift (VACS) characteristics by controlling the distance between the opening of the bank layer and the reflective electrode depending on the wavelength for each subpixel.

According to embodiments of the disclosure, there may be provided a display device capable of enhancing the VACS without reducing the aperture ratio.

According to embodiments of the disclosure, there may be provided a display device with enhanced luminance as light traveling from the light emitting layer to the side surface is re-reflected by the reflective electrode to the outside.

According to embodiments of the disclosure, there may be provided a display device capable of reducing power consumption as the light extraction efficiency is enhanced by the reflective electrode.

### BRIEF DESCRIPTION OF DRAWINGS

The above and other objects, features, and advantages of the disclosure will be more clearly understood from the following detailed description, taken in conjunction with the accompanying drawings, in which:

FIG. 1 is a view illustrating a system configuration of a display device according to an embodiment of the disclosure;

FIG. 2 is a cross-sectional view of the display device of FIG. 1, taken along A-A′ according to an embodiment of the disclosure;

FIG. 3 is a view illustrating an optical path generated in area “A” of the display device of FIG. 2 according to an embodiment of the disclosure;

FIG. 4 is a cross-sectional view illustrating a display device according to another embodiment of the disclosure;

FIG. 5 is a plan view schematically illustrating neighboring subpixels in FIGS. 2 and 4 according to an embodiment of the disclosure;

FIG. 6 is a view illustrating a state in which light is emitted from the subpixel of FIG. 5 according to an embodiment of the disclosure;

FIG. 7 is a plan view illustrating an arrangement of subpixels according to an embodiment of the disclosure; and

FIG. 8 is a plan view illustrating a data line overlapping a subpixel according to an embodiment of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

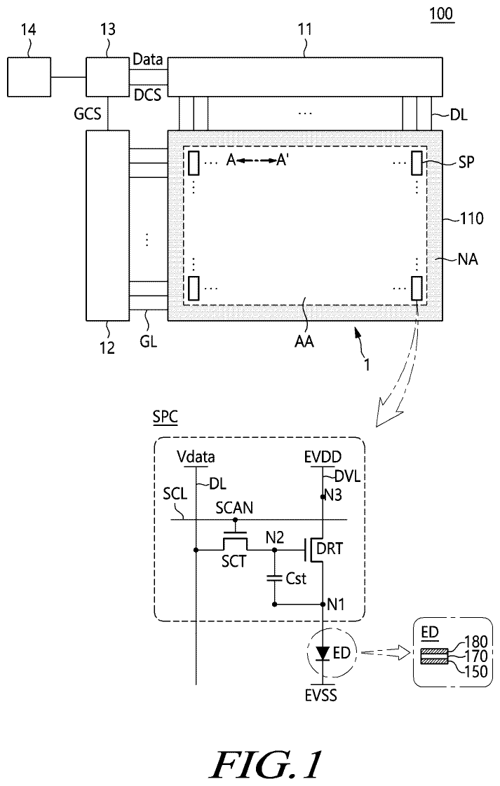

FIG. 1 is a view illustrating a system configuration of a display device according to an embodiment of the disclosure.

Referring to FIG. 1, a display driving system of a display device 100 according to embodiments of the disclosure may include a display panel 1 and display driving circuits for driving the display panel 1.

The display panel 1 may include a display area AA in which images are displayed and a non-display area NA in which no image is displayed. The display panel 1 may include a plurality of subpixels SP disposed on a base substrate 110 for image display.

The display panel 1 may include a plurality of signal lines disposed on the base substrate 110. For example, the plurality of signal lines may include data lines DL, gate lines GL, driving voltage lines DVL, and the like.

Each of the plurality of data lines DL is disposed while extending in a first direction (e.g., a column direction or a row direction), and each of the plurality of gate lines GL is disposed while extending in a direction crossing the first direction.

The display driving circuits may include a data driving circuit 11 and a gate driving circuit 12 and may further include a controller 13 for controlling the data driving circuit 11 and the gate driving circuit 12.

The data driving circuit 11 may output data signals (also referred to as data voltages) corresponding to an image signal to the plurality of data lines DL. The gate driving circuit 12 may generate gate signals and output the gate signals to the plurality of gate lines GL. The controller 13 may convert the input image data input from an external host 14 to meet the data signal format used in the data driving circuit 11 and supply the converted image data to the data driving circuit 11.

The data driving circuit 11 may include one or more source driver integrated circuits. For example, each source driver integrated circuit may be connected with the display panel 1 by a tape automated bonding (TAB) method or connected to a bonding pad of the display panel 1 by a chip on glass (COG) or chip on panel (COP) method or may be implemented by a chip on film (COF) method and connected with the display panel 1.

The gate driving circuit 12 may be connected to the display panel 1 by a tape automatic bonding (TAB) method, connected to a bonding pad of the display panel 1 by a COG or COP method, connected to the display panel 1 by a COF method, or may be formed in the non-display area NA of the display panel 1 by a gate in panel (GIP) method.

Referring to FIG. 1, in the display device 100 according to embodiments of the disclosure, each subpixel SP may include a light emitting element ED and a pixel driving circuit SPC for driving the light emitting element ED. The pixel driving circuit SPC may include a driving transistor DRT, a scan transistor SCT, and a storage capacitor Cst.

The driving transistor DRT may control a current flowing to the light emitting element ED to drive the light emitting element ED. The scan transistor SCT may transfer the data voltage Vdata to the second node N2 which is the gate node of the driving transistor DRT. The storage capacitor Cst may be configured to maintain a voltage for a predetermined period of time.

Th light emitting element ED may include a first electrode 150, a second electrode 180, and a light emitting layer 170 positioned between the first electrode 150 and the second electrode 180 to form a light emitting diode. The first electrode 150 may be a pixel electrode involved in forming the light emitting element ED of each subpixel SP and may be electrically connected to the first node N1 of the driving transistor DRT. The second electrode 180 may be a common electrode involved in forming the light emitting elements ED of all the subpixels SP, and a ground voltage EVSS may be applied thereto.

For example, the light emitting element ED may be an organic light emitting diode OLED, an inorganic light emitting diode (LED), or a quantum dot light emitting element, which is a self-luminous semiconductor crystal.

The driving transistor DRT is a transistor for driving the light emitting element ED, and may include a first node N1, a second node N2, and a third node N3. The first node N1 may be a source node or a drain node, and may be electrically connected to the first electrode 150 of the light emitting element ED. The second node N2 is a gate node and may be electrically connected to the source node or drain node of the scan transistor SCT. The third node N3 may be a drain node or a source node, and may be electrically connected to a driving voltage line DVL that supplies the driving voltage EVDD. For convenience of description, in the example described below, the first node NI may be a source node and the third node N3 may be a drain node.

The scan transistor SCT may switch the connection between the data line DL and the second node N2 of the driving transistor DRT. In response to the scan signal SCAN supplied from the scan line SCL which is a kind of the gate line GL, the scan transistor SCT may control connection between the second node N2 of the driving transistor DRT and a corresponding data line DL among the plurality of data lines DL.

The storage capacitor Cst may be configured between the first node N1 and second node N2 of the driving transistor DRT.

The structure of the subpixel SP illustrated in FIG. 1 is merely an example for description, and may further include one or more transistors, or one or more storage capacitors. The plurality of subpixels SP may have the same structure, or some of the plurality of subpixels SP may have a different structure. Each of the driving transistor DRT and the scan transistor SCT may be an n-type transistor or a p-type transistor.

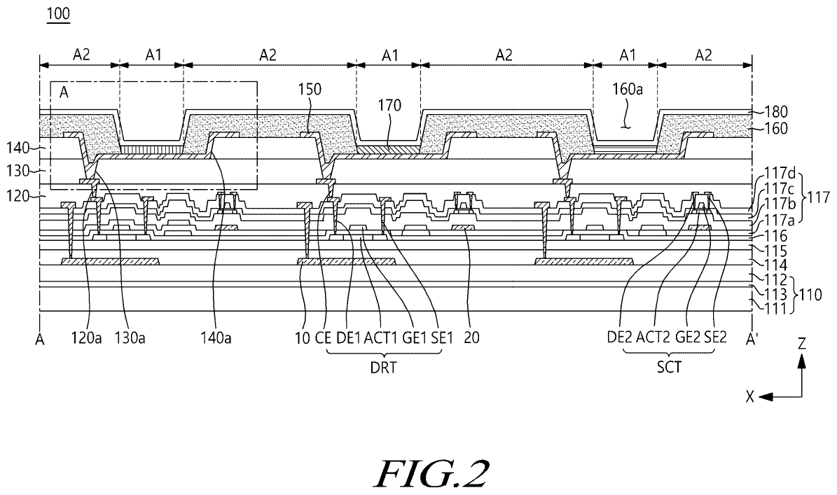

FIG. 2 is a cross-sectional view of the display device of FIG. 1, taken along A-A′ according to an embodiment of the disclosure.

Referring to FIG. 2, the display device 100 may include a base substrate 110, a first planarization layer 120, a second planarization layer 130, a third planarization layer 140, a first electrode 150, a bank layer 160, a light emitting layer 170, and a second electrode 180.

The base substrate 110 is for supporting various components of the display device 100, and may include a display area AA that displays an image and a non-display area NA that does not display an image. The display area AA may include a first area A1 and a second area A2. The first area A1 may be a main emission area MEA in which an organic light emitting diode, formed by the first electrode 150, the light emitting layer 170 and the second electrode 180, is disposed, and the second area A2 may be an area that does not overlap the organic light emitting diode. In some embodiments, the light emitting layer 170 may extend beyond the first area A1, in which case the functioning organic light emitting diode may still be confined within the first area A1 where the first electrode 150, the light emitting layer 170 and the second electrode 180 overlap and are in contact with one another. Specifically, the second area A2 may be an area where the reflected light area REA and the non-emission area NEA in which light in the wave guide mode traveling to the side of the light emitting layer 170 is totally reflected by the first electrode 150 and emitted to the outside coexist. The second area A2 may include a boundary between adjacent subpixels SP and/or the non-display area NA.

The base substrate 110 may be formed of two or more layers. For example, The base substrate 110 may include a first base substrate 111, a second base substrate 112, and an insulation layer 113 disposed between the first base substrate 111 and the second base substrate 112.

The first base substrate 111 and the second base substrate 112 may be formed of polyimide (PI). Polyimide is a polymer with a relatively low degree of crystallization or mostly amorphous structure, and may be easily synthesized to make a thin film-type film, and has advantages such as transparency, heat resistance, and good mechanical properties. However, since polyimide has poor moisture permeability resistance, the insulation layer 113 formed of an inorganic insulating material such as silicon nitride (SiNₓ) or silicon oxide (SiOₓ) may be disposed between the first base substrate 111 and the second base substrate 112 to ensure moisture permeability resistance of the base substrate 110.

A plurality of buffer layers for blocking moisture and oxygen flowing into the second base substrate 112 may be disposed. For example, The buffer layers may include a multi-buffer layer 114 and an active buffer layer 115.

The multi-buffer layer 114 is for blocking moisture and oxygen introduced into the inside, and may be formed of an inorganic material such as silicon nitride (SiNₓ), silicon oxide (SiOₓ), silicon oxynitride (SiON), aluminum oxide (Al₂O₃).

A first light blocking layer 10 may be disposed between the base substrate 110 and the multi-buffer layer 114 to prevent or at least reduce light from entering the driving transistor DRT from the outside. In other words, the multi-buffer layer 114 may be formed to cover the first light blocking layer 10 on the base substrate 110.

The active buffer layer 115 may be disposed on the multi-buffer layer 114. The active buffer layer 115 may be formed of an inorganic material such as silicon nitride (SiNₓ), silicon oxide (SiOₓ), silicon oxynitride (SiON), aluminum oxide (Al₂O₃).

A driving transistor DRT may be disposed between the base substrate 110 and the first planarization layer 120. The driving transistor DRT is for driving the light emitting element ED by controlling a current flowing to the light emitting element ED, and may be electrically connected to the first electrode 150.

The driving transistor DRT may be disposed on the active buffer layer 115, and may include a first active layer ACT1, a first gate electrode GE1, a first source electrode SE1, and a first drain electrode DE1. A first light blocking layer 10 for protecting the first active layer ACT1 may be disposed under the first active layer ACT1.

A plurality of inorganic layers for forming each member of the driving transistor DRT may be formed on the active buffer layer 115. For example, the inorganic layer may include a gate insulation layer 116 and a plurality of interlayer insulation layers 117.

The gate insulation layer 116 may be disposed on the active buffer layer 115 to cover the first active layer ACT1. The first gate electrode GE1 may be disposed on the gate insulation layer 116.

A plurality of interlayer insulation layers 117 may be provided, and may be disposed to cover the first gate electrode GE1 on the gate insulation layer 116. The first source electrode SE1 and the first drain electrode DE1 may be disposed on the interlayer insulation layer 117. In this case, a contact hole through which the first source electrode SE1 and the first drain electrode DE1 pass may be formed in the gate insulation layer 116 and the interlayer insulation layer 117, so that the first source electrode SE1 and the first drain electrode DE1 may be connected to the first active layer ACT1 where a channel is formed when the driving transistor DRT is driven.

The interlayer insulation layer 117 may include a first interlayer insulation layer 117a, a second interlayer insulation layer 117b, a third interlayer insulation layer 117c, and a fourth interlayer insulation layer 117d. A scan transistor SCT including a second active layer ACT2, a second gate electrode GE2, a second source electrode SE2, and a second drain electrode DE2 may be disposed on the interlayer insulation layer 117.

For example, the second active layer ACT2 may be disposed on the second interlayer insulation layer 117b, and the third interlayer insulation layer 117c may be disposed to cover the second active layer ACT2 on the second active layer ACT2. A second gate electrode GE2 may be disposed on the third interlayer insulation layer 117c, and the fourth interlayer insulation layer 117d may be disposed to cover the second gate electrode GE2 on the third interlayer insulation layer 117c. The first source electrode SE1 and the first drain electrode DE1 may be disposed on the fourth interlayer insulation layer 117d. In this case, a contact hole through which the second source electrode SE2 and the second drain electrode DE2 pass may be formed in the third interlayer insulation layer 117c and the fourth interlayer insulation layer 117d, so that the second source electrode SE2 and the second drain electrode DE2 may be connected to the second active layer ACT2.

A second light blocking layer 20 for preventing light from being incident on the scan transistor SCT may be disposed under the scan transistor SCT. For example, the second light blocking layer 20 may be disposed between the first interlayer insulation layer 117a and the second interlayer insulation layer 117b.

The first planarization layer 120 may be disposed on the base substrate 110. For example, the first planarization layer 120 may be formed of an organic material such as photo-acrylic (PAC), and may be disposed on the interlayer insulation layer 117 to cover the first source electrode SE1 and the first drain electrode DE1. Accordingly, the lower step due to the components of the first source electrode SE1 and the first drain electrode DE1 may be alleviated through the first planarization layer 120.

The first planarization layer 120 may include a first contact hole 120a overlapping the hole 140a of the third planarization layer 140 and the driving transistor DRT. As described above, as the first contact hole 120a is formed in the first planarization layer 120, the driving transistor DRT and the first electrode 150 may be electrically connected through a connection electrode CE disposed on the first planarization layer 120. For example, a lower portion of the connection electrode CE may be inserted into the first contact hole 120a, so that the connection electrode CE may contact the driving transistor DRT.

The second planarization layer 130 may be disposed to cover the connection electrode CE on the first planarization layer 120. The second planarization layer 130 may include a second contact hole 130a overlapping the first contact hole 120a.

As described above, as the second contact hole 130a is formed in the second planarization layer 130, a portion of the first electrode 150 may be inserted into the second contact hole 130a so that the first electrode 150 may contact the connection electrode CE.

The third planarization layer 140 may be disposed on the second planarization layer 130, and a plurality of holes 140a exposing a portion of the second planarization layer 130 may be formed. For example, a plurality of holes 140a formed in the third planarization layer 140 may be formed in a portion of the first area A1 and the second area A2 disposed to surround the outer periphery of the first area A1. The hole 140a may be formed to overlap the first contact hole 120a and the second contact hole 130a. In other words, the hole 140a, the first contact hole 120a, and the second contact hole 130a may be disposed to overlap in the Z-axis direction in the drawings.

The first electrode 150 may be disposed to overlap the hole 140a of the third planarization layer 140. For example, a plurality of first electrodes 150 may be provided, and each may be independently disposed in the respective hole 140a. The first electrode 150 in the present embodiment is an anode and may be a reflective electrode. To that end, the first electrode 150 may be formed of an opaque electrode formed of a metal material such as aluminum (Al), copper (Cu), nickel (Ni) or the like having good reflectivity. Further, the second electrode 180 may be formed in a structure in which transparent electrodes such as indium tin oxide (ITO) and indium zinc oxide (IZO) and opaque electrodes are stacked.

The bank layer 160 is for partitioning the first area A1, and may have a plurality of openings 160a to expose a portion of the first electrode 150. For example, the bank layer 160 may be disposed in the second area A2 and may be disposed to cover a portion of the outer periphery of the first electrode 150 and the third planarization layer 140.

The bank layer 160 may have an opening 160a formed in a portion corresponding to the first area A1. For example, the opening 160a of the bank layer 160 may be disposed to overlap the hole 140a and not to overlap the first contact hole 120a and the second contact hole 130a. With this structure, a portion of the first electrode 150 may be exposed to the outside through the opening 160a of the bank layer 160.

A plurality of light emitting layers 170 may be provided and respectively disposed in openings 160a of the bank layer 160. In other words, the light emitting layer 170 may be independently disposed in the first area A1. In some embodiments, the light emitting layer 170 may extend beyond the first area A1, such as onto the side portions of the bank layer 160. The light emitting layer 170 in the present embodiment is an organic compound layer and may be an organic light emitting layer including a hole injection layer (HIL), a hole transport layer (HTL), an active layer (emission material layer (EML)), an electron transfer layer (ETL), and an electron injection layer (EIL).

The second electrode 180 may be disposed on the bank layer 160 and the light emitting layer 170. For example, the second electrode 180 is a cathode and may be disposed in the first area A1 and the second area A2. As a result, an organic light emitting diode may be formed within the first area A1 by the first electrode 150, the light emitting layer 170 and the second electrode 180.

The second electrode 180 may be formed of an opaque electrode such as aluminum (Al), copper (Cu), nickel (Ni), or a transparent electrode such as indium tin oxide (ITO) or indium zinc oxide (IZO). Further, the second electrode 180 may be formed in a structure in which an opaque electrode and a transparent electrode are stacked.

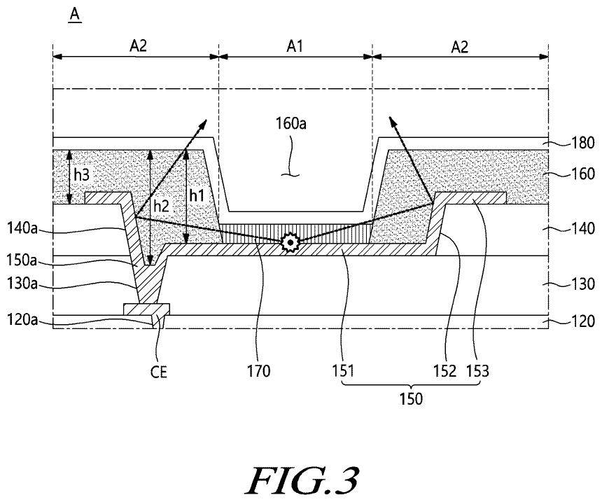

FIG. 3 is a view illustrating an optical path generated in area “A” of the display device of FIG. 2 according to an embodiment of the disclosure.

Referring to FIG. 3, light generated from the light emitting layer 170 may be totally reflected at an interface with a member disposed thereunder and travel to a side surface. This is referred to as a wave guide mode which causes a decrease in light extraction efficiency. To address this issue with light extraction efficiency, the light in the wave guide mode, which travels to the side surface, may be reflected through the first electrode 150 to the outside. In other words, the first electrode 150 may be used as a reflective electrode.

The first electrode 150 may include a first body portion 151, a second body portion 152, and a third body portion 153.

The first body portion 151 may be disposed in the first area A1. For example, the first body portion 151 may be disposed on the second planarization layer 130 exposed to the outside of the hole 140a of the third planarization layer 140.

The second body portion 152 may extend from an end portion of the first body portion 151, and a portion thereof may be disposed on the second planarization layer 130, and the remainder thereof may be disposed on a side portion of the third planarization layer 140. As described above, as a portion of the second body portion 152 is formed on the side portion of the third planarization layer 140, light traveling from the interface between the light emitting layer 170 and the first body portion 151 to the side surface may be re-reflected by the second body portion 152 and emitted to the outside.

A portion of the second body portion 152 may be inserted into the second contact hole 130a formed in the second planarization layer 130 to contact the connection electrode CE, and may thus be electrically connected to the driving transistor DRT. In this case, the portion of the second body portion 152 inserted into the second contact hole 130a may be recessed, forming a step at an upper portion of the second body portion 152.

The second body portion 152 may be disposed to surround the outer periphery of the first body portion 151 in the second area A2, and a protrusion 150a protruding from one side of the first body portion 151 to overlap the second contact hole 130a may be formed. For example, the protrusion 150a may be formed through the second body portion 152 overlapping the second contact hole 130a in the second area A2.

The third body portion 153 may be disposed to surround the outer periphery of the second body portion 152 in the second area A2. For example, the third body portion 153 may extend from an end portion of the second body portion 152 and may be disposed on an upper portion of the third planarization layer 140.

As described above, since the light traveling from the light emitting layer 170 to the side may be totally reflected by the second body portion 152 of the first electrode 150 used as the reflective electrode and extracted to the outside, there may be provided a display device 100 that may be used with low power by enhancing the light extraction efficiency of the display device 100.

Meanwhile, as the first electrode 150 is formed to include a first body portion 151, a second body portion 152, and a third body portion 153, a step may be formed in the first electrode 150. Due to this step structure, the bank layer 160 disposed on the first electrode 150 and the third planarization layer 140 may have a different height at each position. For example, the height h1 of the bank layer 160 disposed between the second contact hole 130a and the first area A1 may be formed to be larger than the height h3 of the bank layer 160 overlapping the third planarization layer 140 and smaller than the height h2 of the bank layer 160 overlapping the second contact hole 130a.

The display device 100 according to the present embodiment may output white light through red, green, and blue subpixels SP. Since the red, green, and blue subpixels SP each have a different wavelength, the luminance reduction may differ from the front to the side, deteriorating the viewing angle color shift (VACS) characteristics. For example, as the luminance of blue light decreases more from the front to the side, the VACS characteristics may deteriorate.

To prevent or at least reduce deterioration of VACS characteristics, it is necessary to set a different separation distance, in a horizontal direction in parallel with the substrate, between the portion of the second body portions 152 of the first electrodes 150 formed on the side portion of the third planarization layer 140 and the opening 160a of the bank layer 160. In other words, the VACS characteristics may be enhanced by controlling the reflection angle of light reflected from the second body portion 152 by setting a different horizontal separation distance between the portion of the second body portion 152 and the opening 160a where the light emitting layer 170 is disposed according to the wavelength for each subpixel SP.

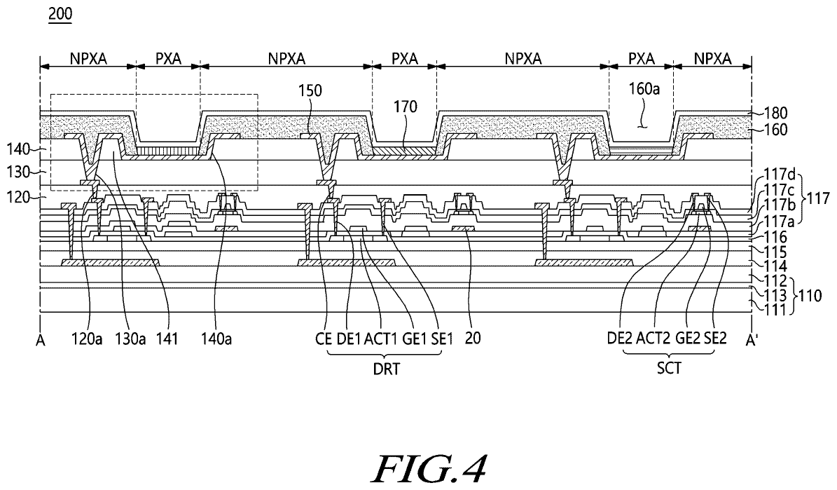

FIG. 4 is a cross-sectional view illustrating a display device according to another embodiment of the disclosure.

Referring to FIG. 4, the display device 200 may control a horizontal separation distance between the portion of the second body portion 152 formed on the side portion of the third planarization layer 140 and the opening 160a of the bank layer 160 by placing a control member 141 formed of the same material as the third planarization layer 140 between the first body portion 151 of the first electrode 150 and the second contact hole 130a. For example, it is possible to control the horizontal separation distance by moving the placement of the control member 141 to the outside or inside depending on the wavelength for each subpixel SP.

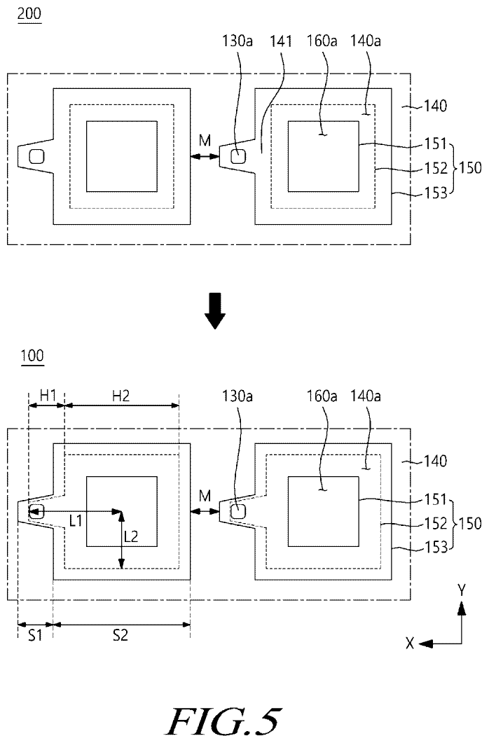

FIG. 5 is a plan view schematically illustrating neighboring subpixels in FIGS. 2 and 4 according to an embodiment of the disclosure.

Referring to FIG. 5, neighboring first electrodes 150 should minimize the process margin M. In this case, if the control member 141 is moved to the area where the second contact hole 130a is placed, it may become difficult to minimize the process margin M. Accordingly, the display device 200 of FIG. 4 secures a horizontal separation control distance between the portion of the second body portions 152 formed on the side portion of the third planarization layer 140 and the opening 160a of the bank layer 160 by reducing the width of the opening 160a, which may reduce the opening rate of the display device 200, thereby deteriorating light extraction efficiency.

To prevent or at least reduce the decrease in aperture ratio, in the display device 100 according to the present embodiment, the second body portion 152 disposed on the second planarization layer 130 may be disposed not to overlap the third planarization layer 140. In other words, to control the horizontal separation distance between the portion of the second body portions 152 and the opening 160a without changing the width of the opening 160a formed in the bank layer 160, the control member 141, which is a portion of the third planarization layer 140, is not disposed between the second contact hole 130a and the first body portion 151. By so doing, the horizontal separation distance between the portion of the second body portions 152 formed on the side portion of the third planarization layer and the opening 160a of the bank layer 160 may be further increased/decreased by the width of the control member 141, and the horizontal separation distance may be controlled without reducing the aperture ratio.

For example, the horizontal distance between the opening 160a and the first electrode 150 may be controlled by resizing the hole 140a formed in the third planarization layer 140. In other words, when the size of the hole 140a of the third planarization layer 140 is formed to be large, the horizontal separation distance between the opening 160a and the portion of the second body portion 152 formed on the side portion of the third planarization layer 140 may also increase, and when the size of the hole 140a is formed to be small, the horizontal separation distance may also decrease.

Referring to FIG. 5, the first electrode 150 of the display device 100 may include a first electrode area S1 overlapping the second contact hole 130a and a second electrode area S2 extending from one side of the first electrode area S1 to overlap the opening 160a. Further, the hole 140a formed in the third planarization layer 140 may include a first hole area H1 extending from an end portion of second body portion 152 overlapping the second contact hole 130a to the nearest side of the outer periphery of the second body portion 152 within the second electrode area S2, and a second hole area H2 extending from one side of the first hole area H1 to the other side of the outer periphery of the second body portion 152, overlapping the opening 160a.

With this structure, the distance L1 between the center of the opening 160a and the end portion of the second body portion 152 disposed in the first hole area Hl may be formed to be larger than the distance L2 between the center of the opening 160a and an end portion of the second body portion 152 disposed in the second hole area H2. Here, the circumference of the first hole area H1 and the second hole area H2 is a portion where the second body portion 152, which is a reflective electrode, is disposed in the first electrode 150, and when the width of the second hole area H2 formed in the third planarization layer 140 varies, the separation distance, in a plan view as shown in FIG. 5, between the outer periphery of the second body portion 152 and the opening 160a may be controlled. In other words, the horizontal distance, in a cross-sectional view as shown in FIG. 3, between the portion of the second body portion 152 formed on the side portion of the third planarization layer 140 and the opening 160a may increase or decrease in proportion to the change in the width of the second hole area H2. Here, the width change of the second hole area H2 means a length change in the X-axis direction and the Y-axis direction in the drawings.

Accordingly, when the width of the second hole area H2 is increased or decreased according to the wavelength for each subpixel SP, the separation distance between the outer periphery of the second body portion 152 and the opening 160a may be set to differ, which may enhance the VACS. Further, since the position of the second body portion 152 extends and moves by the width of the first hole area H1, the separation distance may be formed to be wider by the width of the first hole area H1, so that the VACS may be enhanced without reducing the aperture ratio.

The second hole area H2 may be formed to be extendable up to a point before the second contact hole 130a. This is because when the second hole area H2 overlaps the second contact hole 130a, the size of the first electrode 150 covering the hole 140a also increase, rendering it difficult to secure the minimum process margin M required between neighboring first electrodes 150.

Meanwhile, since the control member 141 is not disposed between the second contact hole 130a and the first body portions 151, the display device 100 according to the present embodiment may increase the width of the opening 160a by the width of the control member 141. Therefore, it is possible to increase the light extraction efficiency by increasing the aperture ratio.

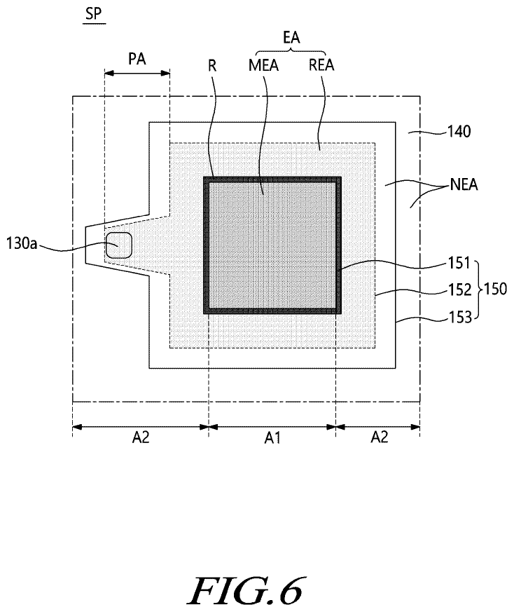

FIG. 6 is a view illustrating a state in which light is emitted from the subpixel of FIG. 5.

Referring to FIG. 6, the subpixel SP disposed in the display area AA may include an emission area EA including a main emission area MEA and a reflected light area REA, and a non-emission area NEA which is an area other than the emission area EA.

The main emission area MEA may be disposed in the first area A1 overlapping the organic light emitting diode formed by the first electrode 150, the light emitting layer 170 and the second electrode 180. In other words, the main emission area MEA is an area in which light generated by the light emitting element ED is emitted through the opening 160a, and may be an area having the highest luminance in the subpixel SP.

The reflected light area REA may be disposed to surround the outer periphery of the main emission area MEA in the second area A2, and have one side portion protruding outward to form a protruding area PA. For example, the protruding area PA may protrude in the direction in which the second contact hole 130a is disposed, and the first contact hole 120a and the second contact hole 130a may be positioned in the protruding area PA.

In the present embodiment, the reflected light area REA may be an area in which light in a wave guide mode traveling to the side portion of the light emitting layer 170 is totally reflected by the second body portion 152 of the first electrode 150 and emitted to the outside. In this case, since the amount of light emitted in the wave guide mode is smaller than the amount of light emitted through the opening 160a, the reflected light area REA may have a lower luminance than the main emission area MEA. Since the area overlapping the bank layer 160 in the second body portion 152 of the first electrode 150 that does not extend onto the side portion of the third planarization layer 140, but disposed on the second planarization layer 130 may be an area in which it is relatively difficult for total reflection to occur. Accordingly, a side ring R may be formed between the main emission area MEA and the reflected light area REA. In other words, the side ring R may be an area having the lowest luminance in the emission area EA. Although not shown, when viewed at plan view, the side ring R may have a protruding shape according to the protruding area PA in the protruding area PA. According to this protruding shape, the width of the side ring R may be the thickest in the protruding area PA.

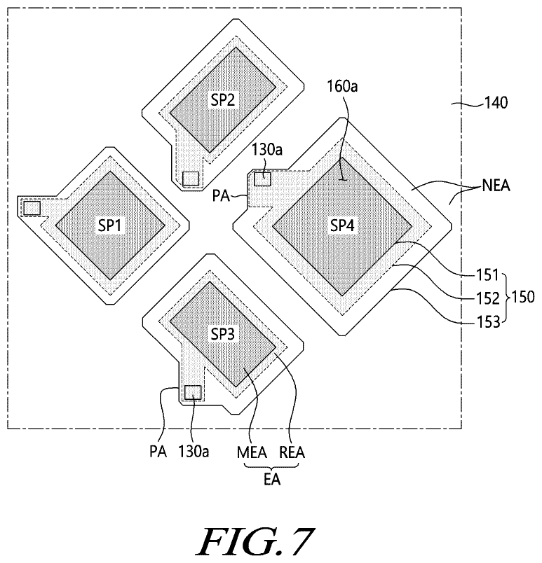

FIG. 7 is a plan view illustrating an arrangement of subpixels according to an embodiment of the disclosure.

Referring to FIG. 7, a subpixels SP may include a first subpixel SP1, a second subpixel SP2, a third subpixel SP3, and a fourth subpixel SP4 adjacent to each other. For example, the first subpixel SP1 may be formed to emit red light, the second subpixel SP2 and the third subpixel SP3 may be formed to emit green light, and the fourth subpixel SP4 may be formed to emit blue light. Since the subpixel SP is formed in a different structure and placement for each color, the intervals between the first subpixel SP1, the second subpixel SP2, the third subpixel SP3, and the fourth subpixel SP4 may be different. Accordingly, the separation distance between the outer periphery of the second body portion 152 and the opening 160a may be extended asymmetrically according to the interval for each subpixel SP.

The first subpixel SP1 and the fourth subpixel SP4 according to the present embodiment may be formed to have a square shape, and the second subpixel SP2 and the third subpixel SP3 may be formed to have an oval or rectangular shape. Further, the protruding areas PA of the first subpixel SP1 and the third subpixel SP3 may protrude outward, and the protruding areas PA of the fourth subpixel SP4 and the second subpixel SP2 may protrude inward. Through this structure, light emission efficiency may be enhanced by maximally arranging a plurality of subpixels on a plane. The protruding areas PA of the second subpixel SP2 and the third subpixel SP3 may point to a first direction, and the protruding areas PA of the first subpixel SP1 and the fourth subpixel SP4 may point to a second direction different from the first direction. The protruding areas PA of the fourth subpixel SP4 and the second subpixel SP2 may be formed to face each other closer than the protruding areas PA of the first subpixel SP1 and the third subpixel SP3.

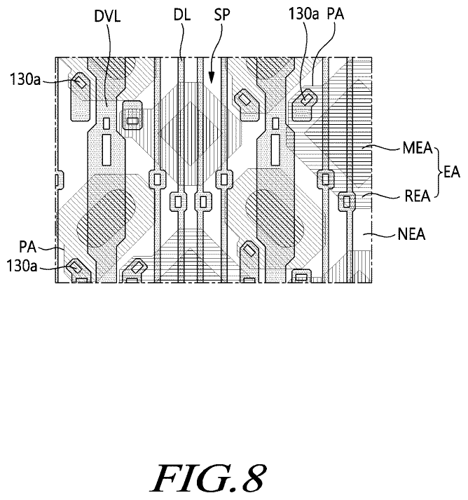

FIG. 8 is a plan view illustrating a data line overlapping a subpixel according to an embodiment of the disclosure.

Referring to FIG. 8, the display device 100 may further include data lines DL electrically connected to the subpixel SP disposed in the first area A1, and the data lines DL may be arranged in a row. When the data lines DL are disposed in a row as described above, more installation space may be secured than by curved data lines, the positions of the first contact hole 120a and the second contact hole 130a may be more easily designed.

A plurality of subpixels SP according to the present embodiment may be provided, and the data line DL may overlap at least two subpixels SP. Further, the data line DL may overlap the reflected light area REA of at least one subpixel SP. Through this structure, light emission efficiency may be enhanced by maximally arranging a plurality of subpixels SP on a plane.

Referring to FIG. 8, the display device 100 may further include a driving voltage line DVL for applying a driving voltage to the subpixel SP, and the protruding area PA may be disposed between the driving voltage line DVL and the data line DL. Accordingly, it may be easy to form the first contact hole 120a and the second contact hole 130a formed in the protruding area PA.

Embodiments of the disclosure described above are briefly described below.

According to embodiments of the disclosure, there may be provided a display device comprising a subpixel including a first area overlapping an organic light emitting diode and a second area not overlapping the organic light emitting diode and disposed to surround an outer periphery of the first area, a main emission area disposed in the first area, and a reflected light area disposed to surround an outer periphery of the main emission area in the second area and having one side portion protruding outward to form a protruding area.

According to embodiments of the disclosure, a side ring may be formed between the main emission area and the reflected light area due to a difference in an amount of light in the main emission area and the reflected light area. According to embodiments of the disclosure, the side ring comprises a protruding shape according to the protruding area. According to embodiments of the disclosure, a width of the side ring is the thickest in the protruding area.

According to embodiments of the disclosure, the subpixel may include a base substrate including the first area and the second area, a first planarization layer disposed on the base substrate and having a first contact hole, a second planarization layer disposed on the first planarization layer and having a second contact hole overlapping the first contact hole, a third planarization layer disposed on the second planarization layer and having a hole overlapping the first contact hole and the second contact hole, a first electrode overlapping the hole of the third planarization layer, a bank layer having an opening formed to expose a portion of the first electrode, a light emitting layer disposed in the opening of the bank layer, and a second electrode disposed on the bank layer and the light emitting layer.

According to embodiments of the disclosure, the protruding area may protrude in a direction in which the second contact hole is disposed.

According to embodiments of the disclosure, the first contact hole and the second contact hole may be positioned in the protruding area.

According to embodiments of the disclosure, the first electrode may include a first body portion disposed in the first area, a second body portion disposed to surround an outer periphery of the first body portion in the second area and having a protrusion protruding from one side of the first body portion to overlap the second contact hole, and a third body portion disposed to surround an outer periphery of the second body portion.

According to embodiments of the disclosure, the second body portion may totally reflect light traveling from the light emitting layer to a side portion, toward the opening.

According to embodiments of the disclosure, the first body portion may be disposed on an upper portion of the second planarization layer. The second body portion may extend from the first body portion and be disposed on an upper portion of the second planarization layer and a side portion of the third planarization layer. The third body portion may extend from the second body portion and is disposed on an upper portion of the third planarization layer.

According to embodiments of the disclosure, there is no portion of the third planarization layer disposed between the second contact hole and the first body portion.

According to embodiments of the disclosure, the display device may further comprise a driving transistor disposed on the base substrate and a connection electrode disposed on the first planarization layer and having a portion inserted into the first contact hole to electrically connect the first electrode and the driving transistor.

According to embodiments of the disclosure, the first electrode may contact the connection electrode as a portion of the first electrode is inserted into the second contact hole.

According to embodiments of the disclosure, a horizontal distance between the opening and a portion of second body portion of the first electrode disposed on the side portion of the third planarization layer is controlled by resizing the hole of the third planarization layer.

According to embodiments of the disclosure, a height of the bank layer disposed between the second contact hole and the first area may be formed to be larger than a height of the bank layer overlapping the third planarization layer, and to be smaller than a height of the bank layer overlapping the second contact hole.

According to embodiments of the disclosure, the opening may overlap the hole of the third planarization layer and may not overlap the first contact hole and the second contact hole.

According to embodiments of the disclosure, the first electrode may include a first electrode area overlapping the second contact hole and a second electrode area extending from a side of the first electrode area and overlapping the opening.

According to embodiments of the disclosure, the hole formed in the third planarization layer may include a first hole area extending from an end portion of second body portion overlapping the second contact hole to the nearest side of the outer periphery of the second body portion within the second electrode area; and a second hole area extending from a side of the first hole area to the other side of the outer periphery of the second body portion, overlapping the opening.

According to embodiments of the disclosure, a separation distance between the opening and the outer periphery of the second body portion may be controlled by changing a width of the second hole area.

According to embodiments of the disclosure, the second hole area may be formed to be extendable up to a point before the second contact hole.

According to embodiments of the disclosure, a distance from a center of the opening to an end portion of the second body portion disposed in the first hole area may be formed to be larger than a straight-line distance from the center of the opening to an end portion of the second body portion disposed in the second hole area.

According to embodiments of the disclosure, the subpixel may include a first subpixel, a second subpixel, a third subpixel, and a fourth subpixel adjacent to each other. The first subpixel and the fourth subpixel may be formed to have a rectangular shape, and the second subpixel and the third subpixel may be formed to have an oval shape.

According to embodiments of the disclosure, the first subpixel and the fourth subpixel may be disposed to be symmetrical in a horizontal axis, and the second subpixel and the third subpixel may be disposed to be symmetrical in a vertical axis.

According to embodiments of the disclosure, protruding areas of the first subpixel and the third subpixel may protrude in an outward direction, and protruding areas of the fourth subpixel and the second subpixel may protrude in an inward direction.

According to embodiments of the disclosure, the display device may further comprise a data line electrically connected to the subpixel, wherein the data line is disposed in a row.

According to embodiments of the disclosure, a plurality of subpixels may be provided. The data line may overlap at least two subpixels.

According to embodiments of the disclosure, a plurality of subpixels may be provided. The data line may overlap a reflected light area of at least one of the subpixels.

According to embodiments of the disclosure, the display device may further comprise a driving voltage line applying a driving voltage to the subpixel. The protruding area may be disposed between the driving voltage line and the data line.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

### DESCRIPTIONS OF REFERENCE NUMBERS

100: display device
110: base substrate
120: first planarization layer
130: second planarization layer
140: third planarization layer
150: first electrode
151: first body portion
152: second body portion
153: third body portion
160: bank layer
170: light emitting layer
180: second electrode

What is claimed is:

1. A display device, comprising:
a subpixel including a first area overlapping an organic light emitting diode, and a second area that is non-overlapping with the organic light emitting diode and surrounds an outer periphery of the first area;
a main emission area in the first area; and
a reflected light area surrounding an outer periphery of the main emission area in the second area, the reflected light area having one side portion protruding outward such that a protruding area is formed.

2. The display device of claim 1, further comprising:
a side ring between the main emission area and the reflected light area.

3. The display device of claim 2, wherein the side ring comprises a protruding shape according to the protruding area.

4. The display device of claim 3, wherein a width of the side ring is thickest in the protruding area.

5. The display device of claim 1, wherein the subpixel further includes:
a base substrate including the first area and the second area;
a first planarization layer on the base substrate, the first planarization layer having a first contact hole;
a second planarization layer on the first planarization layer, the second planarization layer having a second contact hole overlapping the first contact hole.

6. The display device of claim 5, wherein the protruding area protrudes in a direction in which the second contact hole is disposed.

7. The display device of claim 5, wherein the first contact hole and the second contact hole are positioned in the protruding area.

8. The display device of claim 5, wherein a horizontal distance between an opening and a portion of a second body portion of a first electrode disposed on a side portion of a third planarization layer is controlled by resizing a hole of the third planarization layer.

9. The display device of claim 8, wherein a height of a bank layer disposed between the second contact hole and the first area is larger than a height of the bank layer overlapping the third planarization layer, and smaller than a height of the bank layer overlapping the second contact hole.

10. The display device of claim 8, wherein the opening overlaps the hole of the third planarization layer without overlapping the first contact hole and the second contact hole.

11. The display device of claim 8, wherein the first electrode includes:
a first electrode area overlapping the second contact hole; and
a second electrode area extending from a side of the first electrode area and overlapping the opening.

12. The display device of claim 11, wherein the hole in the third planarization layer includes:
a first hole area extending from an end portion of second body portion overlapping the second contact hole to a nearest side of an outer periphery of the second body portion within the second electrode area; and
a second hole area extending from a side of the first hole area to another side of the outer periphery of the second body portion, the second hole area overlapping the opening.

13. The display device of claim 12, wherein a separation distance between the opening and the outer periphery of the second body portion is controlled by changing a width of the second hole area.

14. The display device of claim 13, wherein a distance from a center of the opening to an end portion of the second body portion disposed in the first hole area is larger than a distance from the center of the opening to an end portion of the second body portion disposed in the second hole area.

15. The display device of claim 1, wherein the subpixel includes a first subpixel, a second subpixel, a third subpixel, and a fourth subpixel adjacent to each other, and
wherein the first subpixel and the fourth subpixel have a rectangular shape, and the second subpixel and the third subpixel have an oval shape.

16. The display device of claim 15, wherein the first subpixel and the fourth subpixel are symmetrical in a horizontal axis, and the second subpixel and the third subpixel are symmetrical in a vertical axis.

17. The display device of claim 15, wherein protruding areas of the first subpixel and the third subpixel protrude in an outward direction, and protruding areas of the fourth subpixel and the second subpixel protrude in an inward direction.

18. The display device of claim 1, further comprising:
a data line electrically connected to the subpixel, wherein the data line is in a row.

19. The display device of claim 18, wherein a plurality of subpixels are provided, and the data line overlaps at least two subpixels.

20. The display device of claim 19, wherein a plurality of subpixels are provided, and the data line overlaps a reflected light area of at least one of the plurality of subpixels.
